(19) United States
(12) Patent Application Publication
(10) Pub. No.: US 2026/0182014 A1
(43) Pub. Date: Jun. 25, 2026

(54) GATE STRUCTURE AND METHODS FOR MANUFACTURING THE SAME

(71) Applicant: TAIWAN SEMICONDUCTOR MANUFACTURING COMPANY, LTD., Hsinchu (TW)

(72) Inventors: Yi-Hsuan CHEN, Hsinchu (TW); Pei Ying LAI, Hsinchu (TW); Cheng-Hao HOU, Hsinchu (TW); Chi On CHUI, Hsinchu (TW); Jia-Yun XU, Hsinchu (TW)

(21) Appl. No.: 19/177,318

(22) Filed: Apr. 11, 2025

Related U.S. Application Data
(60) Provisional application No. 63/737,845, filed on Dec. 23, 2024.

(51) Int. Cl. H10D 84/85; H10D 30/00; H10D 30/01; H10D 30/43; H10D 62/10; H10D 62/13; H10D 64/27; H10D 64/68; H10D 84/01

(52) U.S. Cl. CPC H10D 84/851; H10D 30/014; H10D 30/0191; H10D 30/43; H10D 30/502; H10D 30/503; H10D 62/121; H10D 62/151; H10D 64/514; H10D 64/518; H10D 64/685; H10D 64/693; H10D 84/0181; H10D 84/856

(57) ABSTRACT

A method for forming a semiconductor device structure includes forming an IL to surround each semiconductor channel layer at first and second device regions, forming a HK dielectric layer over the IL, forming a tuning layer over the HK dielectric layer, the tuning layer comprising elements for devices having a first conductivity, forming a dipole layer over the tuning layer at the first and second device regions, wherein the tuning layer and the dipole layer are sequentially formed in a processing chamber without breaking the vacuum, and the dipole layer comprises elements suitable for devices having the first conductivity type, removing the dipole layer over the semiconductor channel layers at the second device region, subjecting the tuning layer to a thermal treatment to drive elements from the tuning layer into the HK dielectric layer at the first device region, removing the dipole layer and the tuning layer over the semiconductor channel layers at the first device region, and forming a gate electrode layer to surround each semiconductor channel layer at the first and second device regions.

### CROSS-REFERENCE TO RELATED APPLICATIONS

This application claims priority to U.S. Provisional Application Ser. Nos. 63/737,845 filed Dec. 23, 2024, which is incorporated by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 are perspective views of various stages of manufacturing a semiconductor device structure in accordance with some embodiments.

FIGS. 6A, 6B, and 6C are cross-sectional side views of the semiconductor device structure taken along line A-A, line B-B, and line C-C of FIG. 5, respectively.

FIGS. 7A-12A and 23A are cross-sectional side views of various stages of manufacturing the semiconductor device structure taken along cross-section A-A of FIG. 5, in accordance with some embodiments.

FIGS. 7B-12B and 23B are cross-sectional side views of various stages of manufacturing the semiconductor device structure taken along cross-section B-B of FIG. 5, in accordance with some embodiments.

FIGS. 7C-12C and 23C are cross-sectional side views of various stages of manufacturing the semiconductor device structure taken along cross-section C-C of FIG. 5, in accordance with some embodiments.

FIG. 15-1 is an embodiment showing the tuning layer includes a first layer and a second layer.

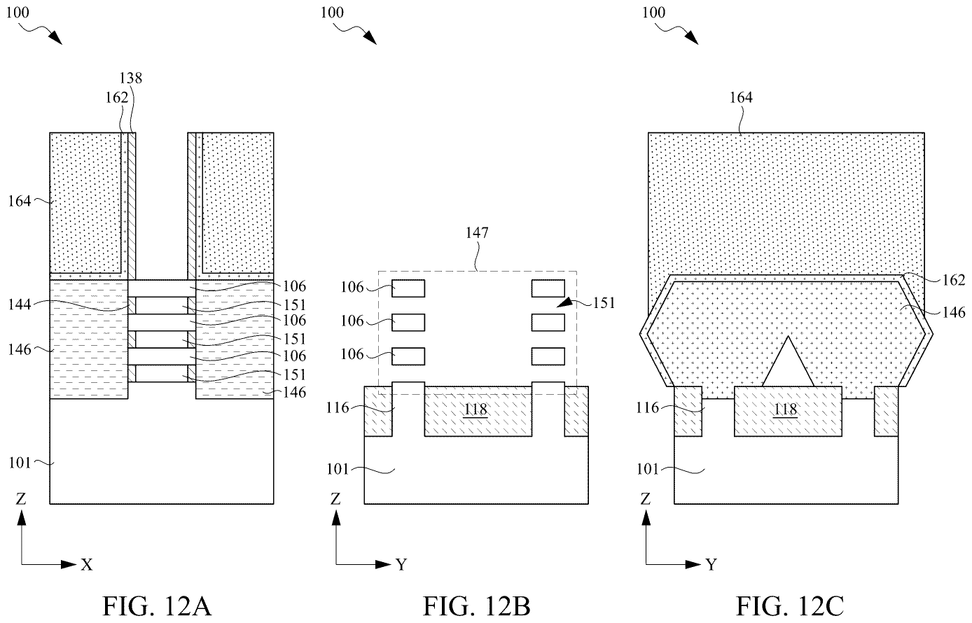

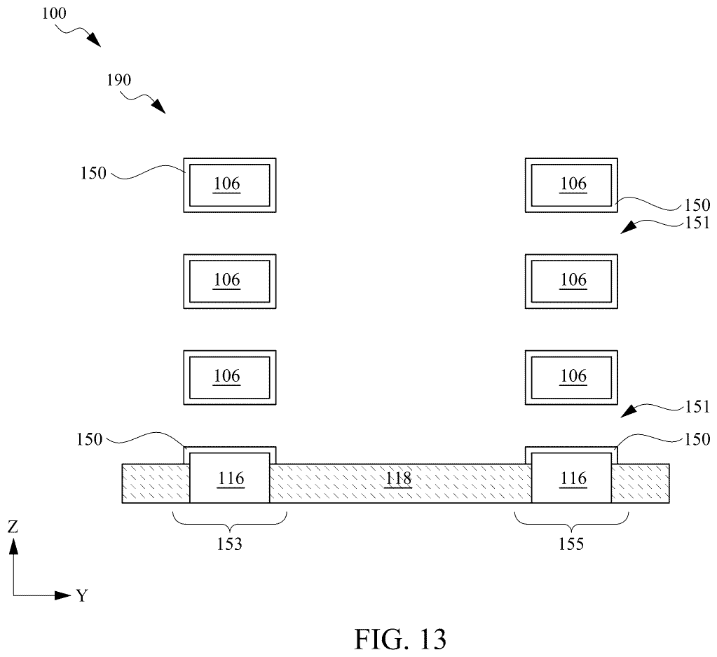

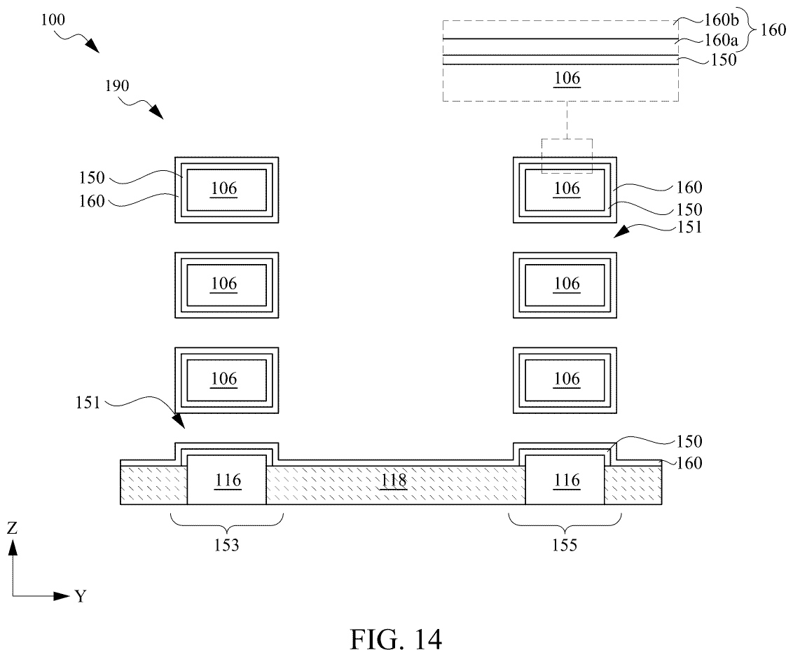

FIGS. 13-15 and 16-19 are enlarged views of a region of FIG. 12B showing various stages of manufacturing replacement gate structure for the semiconductor device structure, in accordance with some embodiments.

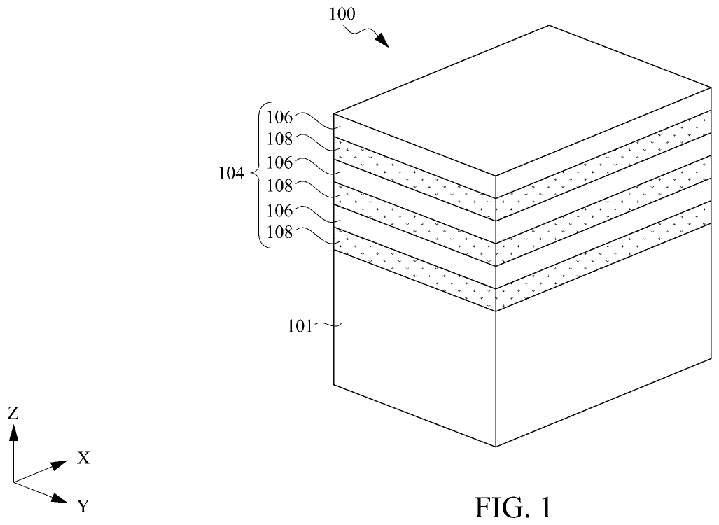

FIG. 19-1 is an enlarged view of a portion of the semiconductor device structure showing the intermixed layer in the modified HK dielectric layer, in accordance with some embodiments.

FIGS. 20 and 21 are enlarged views of a region of FIG. 12B showing various stages of manufacturing replacement gate structure for the semiconductor device structure, in accordance with some embodiments.

FIG. 22 shows an enlarged view of a portion of the semiconductor device structure of FIG. 21, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as planar FETs, three-dimensional fin-like FETs (FinFETs), gate-all-around (GAA) devices (e.g., Horizontal Gate All Around (HGAA) FETs, Vertical Gate All Around (VGAA) FETs), vertical FETs, forksheet FETs, or complementary FETs (CFETs). While the embodiments of this disclosure are discussed with respect to GAA devices, implementations of some aspects of the present disclosure may be used in other processes and/or in other devices. A person having ordinary skill in the art will readily understand other modifications that may be made are contemplated within the scope of this disclosure.

For GAA devices using high-K metal gate (HKMG) scheme, the transistor channel layers are wrapped around with various layers such as interfacial layers (ILs), high-K (HK) gate dielectric, and metal gate layers. Additional layers may be disposed between the metal gate layers and the high-K gate dielectric to adjust threshold voltage (Vₜₕ) for the GAA devices. For example, a dipole layer may be disposed between the metal gate layer and the high-K gate dielectric to modify the flat-band voltage (V_{FB}) of the gate structure in GAA devices and shift their threshold voltages. However, with the trend of scaling, the devices size and the device footprint (i.e., a physical space required by a device) are getting smaller and smaller, which reduces the space between the transistor channel layers and affects the Vₜₕ tuning ability, resulting in a decrease in the effective capacitance of the GAA device due to an increase in the capacitance-equivalent thickness (CET) value. The CET value represents an effective electrical thickness of a gate dielectric layer in a transistor. A lower CET value is desirable in advanced semiconductor devices as it allows for higher capacitance, improved control over the transistor channel layers, and better device performance without increasing leakage currents. Various embodiments of the present disclosure provide an improved approach of using tuning layers (formed of metal nitrides) and cluster mask layer as bilayer p-dipole layers for controlling the V_{FB} of the gate structure without CET penalty.

FIGS. 1-23C show exemplary processes for manufacturing a semiconductor device structure 100 according to embodiments of the present disclosure. It is understood that additional operations can be provided before, during, and after processes shown by FIGS. 1-23C, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100 (e.g., nano-FET), in accordance with some embodiments. As shown in FIG. 1, a semiconductor device structure 100 includes a stack of semiconductor layers 104 formed over a front side of a substrate 101. The substrate 101 may be a semiconductor substrate, such as a bulk semiconductor, or the like. The substrate 101 may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer. Other substrates, such as single-layer, multi-layered, or gradient substrates may also be used.

The substrate 101 may include various regions that have been doped with impurities (e.g., dopants having P-type or N-type conductivity). Depending on circuit design, the dopants may be, for example boron for a P-type field effect transistors (PFET) and phosphorus for an N-type field effect transistors (NFET).

The stack of semiconductor layers 104 includes alternating semiconductor layers made of different materials to facilitate formation of nanosheet channels in a multi-gate device, such as nanosheet channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of a first semiconductor material suitable for N-type nano-FETs, such as silicon, silicon carbide, or the like, and the second semiconductor layers 108 may be made of a second semiconductor material suitable for P-type nano-FETs, such as silicon germanium or the like. In some examples, the first semiconductor layers 106 may be made of Si and the second semiconductor layers 108 may be made of SiGe. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof. Each of the layers of the stack of semiconductor layers 104 may be epitaxially grown using a process such as chemical vapor deposition (CVD), atomic layer deposition (ALD), vapor phase epitaxy (VPE), molecular beam epitaxy (MBE), a metalorganic chemical vapor deposition (MOCVD) process, or other suitable growth processes.

Due to high etch selectivity between the first semiconductor materials and the second semiconductor materials, the second semiconductor material of the second semiconductor layers 108 may be removed without significantly removing the first semiconductor material of the first semiconductor layers 106, thereby allowing the first semiconductor layers 106 to be patterned to form nanosheet or nanostructure channel(s) of the semiconductor device structure 100 in later fabrication stages. The term nanosheet or nanostructure channels is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. Although the stack of semiconductor layers 104 is illustrated as including a second semiconductor layer 108 as the bottommost layer, in some embodiments, the bottommost layer of the stack of semiconductor layers 104 may be a first semiconductor layer 106.

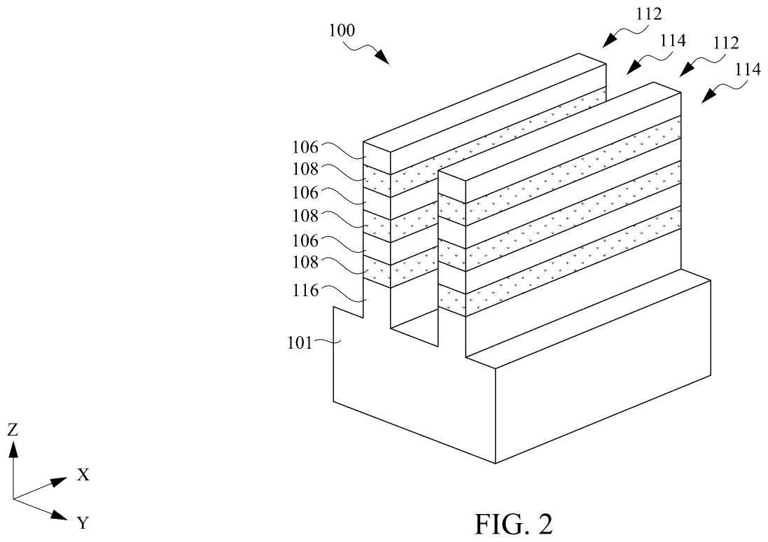

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using one or more photolithography processes and etching processes. The etching process can include dry etching, wet etching, reactive ion etching (RIE), and/or other suitable processes. The photolithography process may include double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the the fin structures 112. In any case, the one or more etching processes form trenches 114 in unprotected regions through the hard mask layer, through the stack of semiconductor layers 104, and into the substrate 101, thereby leaving the plurality of extending fin structures 112. The trenches 114 extend along the X direction.

FIG. 2 further illustrates the fin structures 112 having substantially vertical sidewalls, such that width of the fin structures 112 are substantially similar and each of the first and second semiconductor layers 106, 108 in the fin structures 112 is rectangular in shape. In some embodiments, the fin structures 112 may have tapered sidewalls, such that a width of each of the fin structures 112 continuously increases in a direction towards the substrate 101. In such cases, each of the first and second semiconductor layers 106, 108 in the fin structures 112 may have a different width and be trapezoidal in shape.

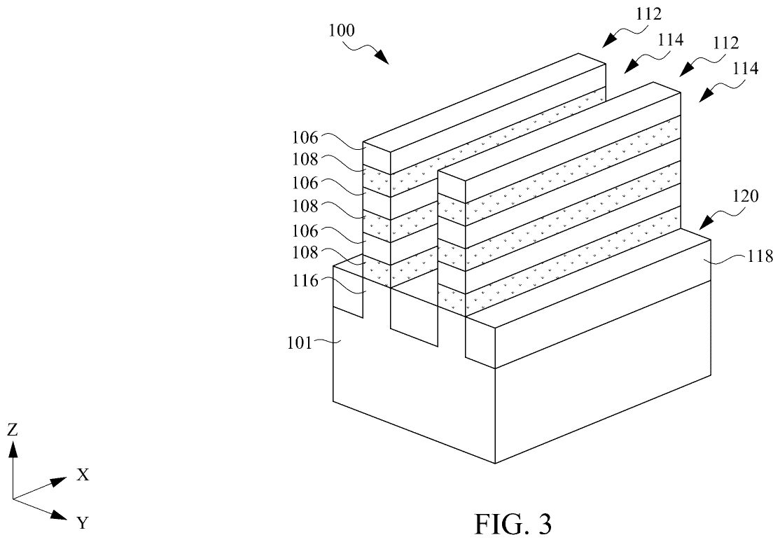

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

Thereafter, the insulating material 118 is recessed to form an isolation region 120. After recessing, portions of the fin structures 112, such as the stack of semiconductor layers 104, may protrude from between neighboring isolation regions 120. The isolation regions 120 may have top surfaces that are flat as illustrated, convex, concave, or a combination thereof. The recess of the insulating material 118 reveals the trenches 114 between the neighboring fin structures 112. The isolation region 120 may be formed using a suitable process, such as a dry etching process, a wet etching process, or a combination thereof. In one embodiment, the isolation regions 120 are formed using dilute hydrofluoric acid (dHF), which is selective to the insulating material 118 over the stack of semiconductor layers 104. Upon completion of recessing, a top surface of the insulating material 118 may be level with or below a surface of the second semiconductor layers 108 in contact with the well portion 116 formed from the substrate 101.

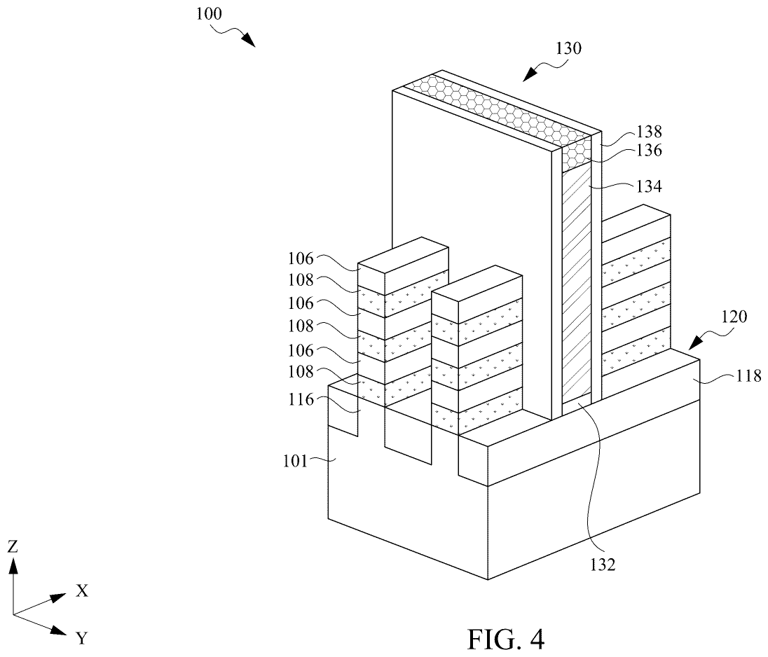

In FIG. 4, one or more sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed over sidewalls of the sacrificial gate structures 130. The gate spacers 138 may be formed by conformally depositing one or more layers for the gate spacers 138 and anisotropically etching the one or more layers, for example. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. In some cases, some S/D regions may be shared between various transistors. For example, various one of the S/D regions may be connected together and implemented as multiple functional transistors. It should be understood that the source region and the drain region can be interchangeably used since the epitaxial features to be formed in these regions are substantially the same.

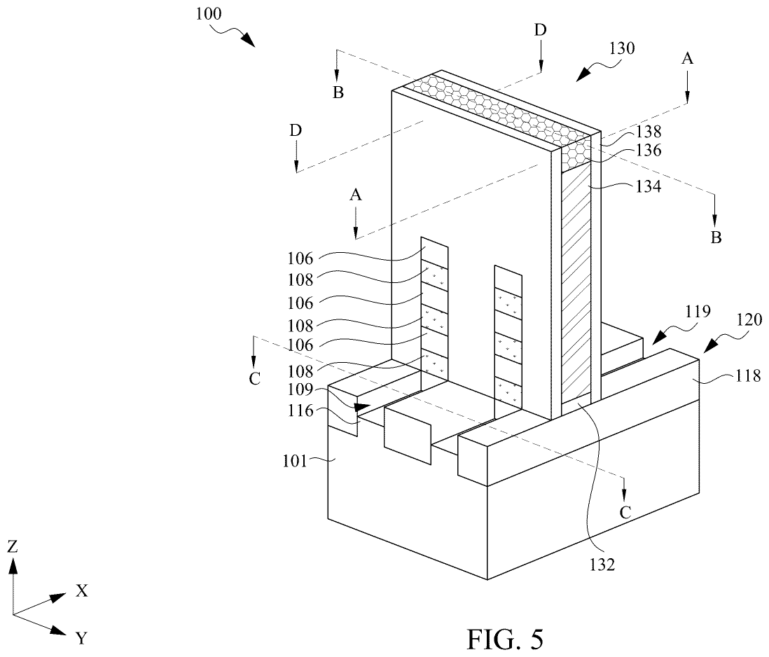

In FIG. 5, the portions of the fin structures 112 in the S/D regions (e.g., regions on opposite sides of the sacrificial gate structure 130) are recessed down below the top surface of the isolation region 120 (or the insulating material 118), by removing portions of the fin structures 112 not covered by the sacrificial gate structure 130. The recess of the portions of the fin structures 112 can be done by an etch process, either isotropic or anisotropic etch process, or further, may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. Trenches 119 are formed in the S/D regions as the result of the recess of the portions of the fin structures 112.

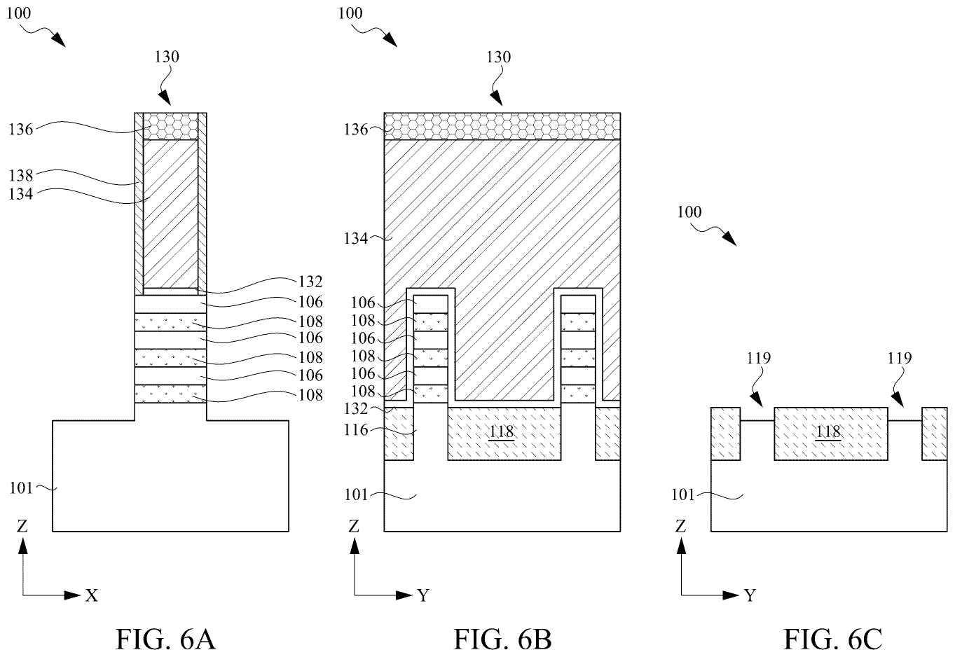

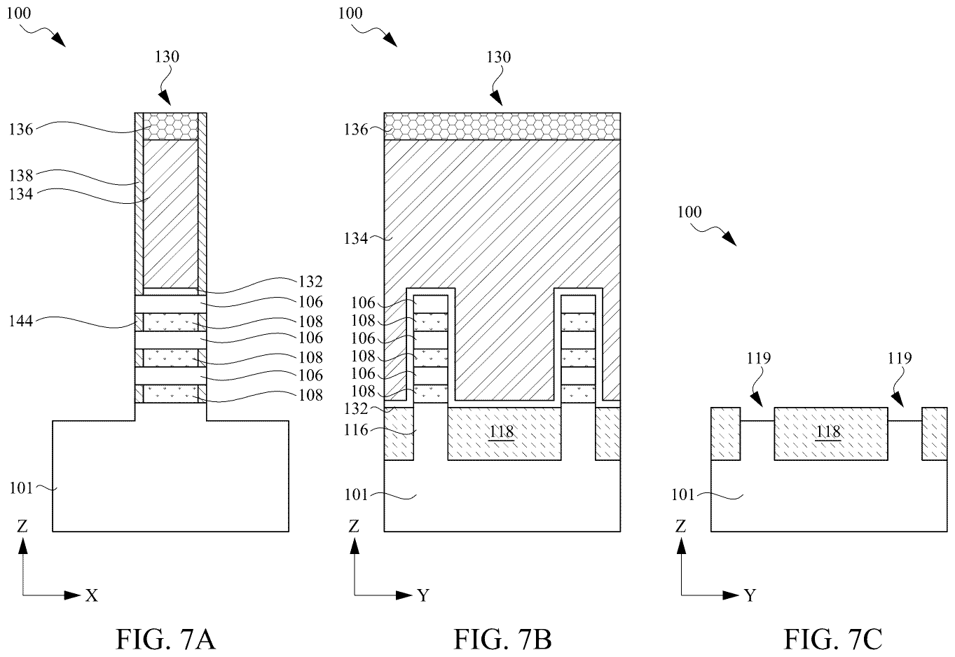

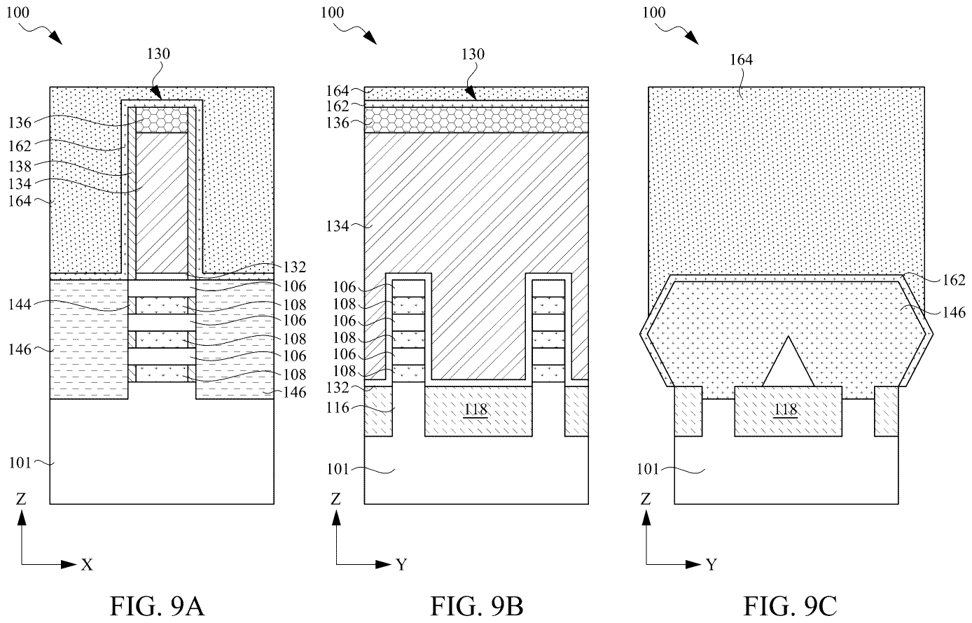

FIGS. 6A, 6B, and 6C are cross-sectional side views of the semiconductor device structure 100 taken along line A-A, line B-B, and line C-C of FIG. 5, respectively. FIGS. 7A-12A and 23A are cross-sectional side views of various stages of manufacturing the semiconductor device structure 100 taken along cross-section A-A of FIG. 5, in accordance with some embodiments. FIGS. 7B-12B and 23B are cross-sectional side views of various stages of manufacturing the semiconductor device structure 100 taken along cross-section B-B of FIG. 5, in accordance with some embodiments. FIGS. 7C-12C and 23C are cross-sectional side views of various stages of manufacturing the semiconductor device structure 100 taken along cross-section C-C of FIG. 5, in accordance with some embodiments. Cross-section A-A is in a plane of the fin structure 112 (channel/fin cut) along the X direction. Cross-section B-B is in a plane perpendicular to cross-section A-A and is in the sacrificial gate structure 130 (gate cut). Cross-section C-C is in a plane perpendicular to cross-section A-A and is in the source/drain region (e.g., epitaxial S/D features 146 shown in FIG. 9A) along the Y-direction.

In FIGS. 7A-7C, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etching process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers (or so-called inner spacer) 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

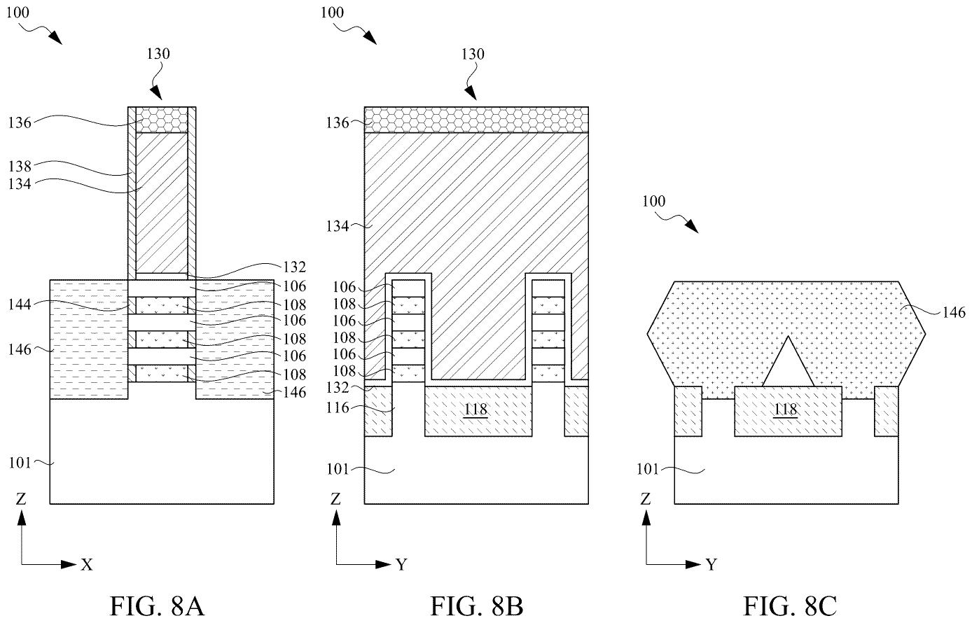

In FIGS. 8A-8C, epitaxial S/D features 146 are formed in the source/drain (S/D) regions. The epitaxial S/D features 146 are formed such that each sacrificial gate structure 130 is disposed between respective neighboring pairs of the S/D regions. In one example shown in FIG. 9A, one of a pair of epitaxial S/D features 146 disposed on one side of the sacrificial gate structure 130 is designated as a source feature/terminal, and the other of the pair of epitaxial S/D features 146 disposed on the other side of the sacrificial gate structure 130 is designated as a drain feature/terminal. The source feature/terminal and the drain feature/terminal are connected by the channel layers (e.g., the first semiconductor layers 106). The epitaxial S/D features 146 are in contact with the first semiconductor layer 106 under the sacrificial gate structure 130. In some cases, the epitaxial S/D features 146 may grow pass the topmost semiconductor channel, i.e., the first semiconductor layer 106 under the sacrificial gate structure 130, to be in contact with the gate spacers 138. The second semiconductor layer 108 under the sacrificial gate structure 130 are separated from the epitaxial S/D features 146 by the dielectric spacers 144.

The epitaxial S/D features 146 may grow both vertically and horizontally to form facets, which may correspond to crystalline planes of the material used for the substrate 101. In some cases, the epitaxial S/D features 146 of a fin structure may grow and merge with the epitaxial S/D features 146 of the neighboring fin structures, as one example shown in FIG. 8C.

The epitaxial S/D features 146 may be made of one or more layers of Si, SiP, SiC and SiCP for n-channel FETs or Si, SiGe, Ge for p-channel FETs. The epitaxial S/D features 146 may be formed by an epitaxial growth method using CVD, ALD or MBE. The epitaxial S/D features 146 may be implanted with dopants followed by an anneal. N-type and/or P-type impurities for epitaxial S/D features 146 may be any of the dopants discussed previously.

In FIGS. 9A-9C, a contact etch stop layer (CESL) 162 is conformally formed on the exposed surfaces of the semiconductor device structure 100. The CESL 162 covers the sidewalls of the sacrificial gate structure 130, the insulating material 118, the epitaxial S/D features 146, and the exposed surface of the stack of semiconductor layers 104. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, a first interlayer dielectric (ILD) layer 164 is formed on the CESL 162 over the semiconductor device structure 100. The materials for the first ILD layer 164 may include compounds comprising Si, O, C, and/or H, such as silicon oxide, TEOS oxide, SiCOH and SiOC. Organic materials, such as polymers, may also be used for the first ILD layer 164. The first ILD layer 164 may be deposited by a PECVD process or other suitable deposition technique. In some embodiments, after formation of the first ILD layer 164, the semiconductor device structure 100 may be subject to a thermal process to anneal the first ILD layer 164.

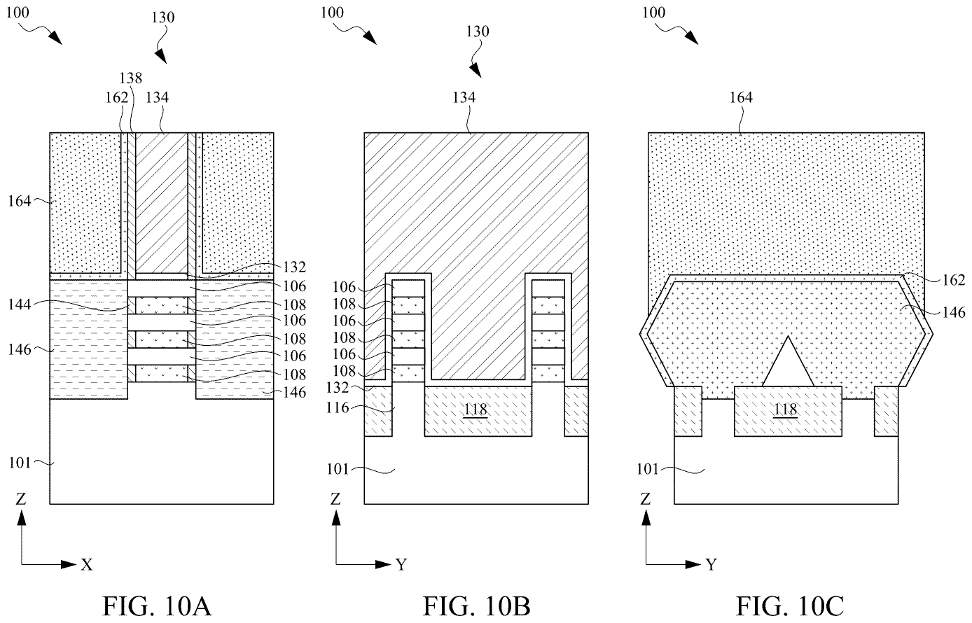

In FIGS. 10A-10C, after the first ILD layer 164 is formed, a planarization operation, such as CMP, is performed on the semiconductor device structure 100 until the sacrificial gate electrode layer 134 is exposed.

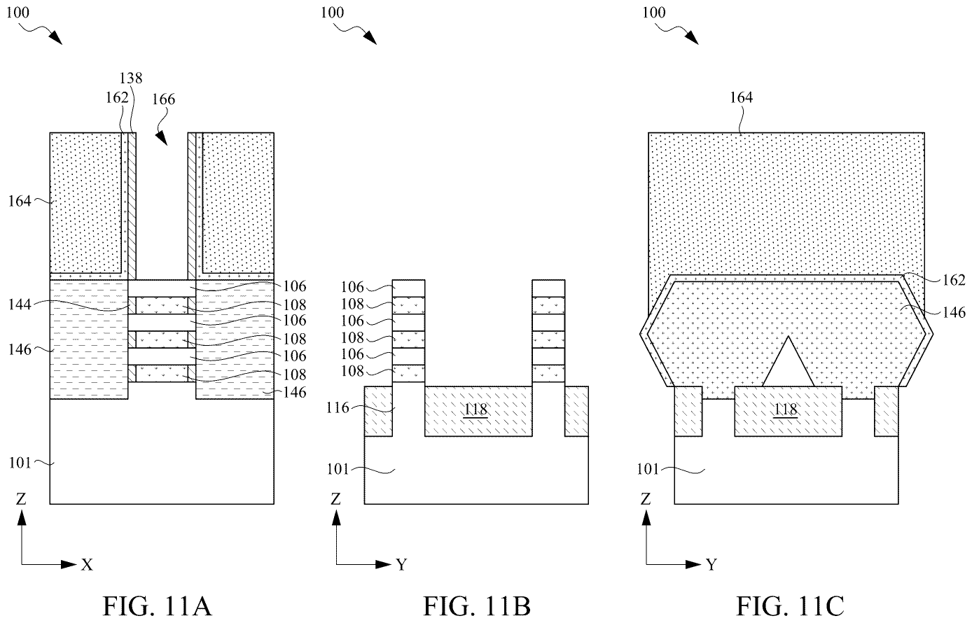

In FIGS. 11A-11C, the sacrificial gate structure 130 is removed. The first ILD layer 164 protects the epitaxial S/D features 146 during the removal of the sacrificial gate structure 130. The sacrificial gate structure 130 can be removed using plasma dry etching and/or wet etching. For example, in cases where the sacrificial gate electrode layer 134 is polysilicon and the first ILD layer 164 is silicon oxide, a wet etchant such as a tetramethylammonium hydroxide (TMAH) solution can be used to selectively remove the sacrificial gate electrode layer 134 without removing the dielectric materials of the first ILD layer 164, the CESL 162, and the gate spacers 138. The sacrificial gate dielectric layer 132 is thereafter removed using plasma dry etching and/or wet etching. The removal of the sacrificial gate structure 130 (i.e., the sacrificial gate electrode layer 134 and the sacrificial gate dielectric layer 132) forms a trench 166 in the regions where the sacrificial gate electrode layer 134 and the sacrificial gate dielectric layer 132 were removed. The trench 166 exposes the top and sides of the stack of semiconductor layers 104 (e.g., the first semiconductor layers 106 and the second semiconductor layers 108).

In FIGS. 12A-12C, the exposed second semiconductor layers 108 are removed. The removal of the second semiconductor layers 108 exposes the dielectric spacers 144 and the first semiconductor layers 106. The removal process may be any suitable etch processes, such as dry etch, wet etch, or a combination thereof. The etch process may be a selective etch process that removes the second semiconductor layers 108 but without substantially attacking the first semiconductor layers 106. In some embodiments, the etch process is an isotropic etching process using an etching gas, and optionally, a carrier gas, where the etching gas comprises F₂ and HF, and the carrier gas may be an inert gas such as Ar, He, N₂, combinations thereof, or the like. Upon removal of the second semiconductor layers 108, openings 151 are formed around the first semiconductor layers 106, and the portion of the first semiconductor layers 106 not covered by the dielectric spacers 144 is exposed to the openings 151. The remaining first semiconductor layers 106 may serve as channel regions for the GAA devices, which may include at least an NFET or a PFET in some embodiments. While not specifically shown, one of the GAA devices, such as the semiconductor device structure 100, may be an NFET or a PFET, in accordance with some embodiments.

FIGS. 13-16 are enlarged views of a region 147 of FIG. 12B showing various stages of manufacturing replacement gate structure 190 for the semiconductor device structure 100, in accordance with some embodiments. As discussed above, the substrate 101 may include various regions that have been doped with impurities (e.g., dopants having P-type or N-type conductivity). In one exemplary embodiment, the substrate 101 has a device region 153 and a device region 155 adjacent to the device region 153. The device region 153 may be designated as a P-type region or an N-type region, and the device region 155 may be designated as an N-type region or a P-type region. Alternatively, both regions 153, 155 may be designated as a P-type region or N-type region. In one embodiment, the device region 153 is a P-type region and the device region 155 is an N-type region. While not shown in scale in some figures, the device region 153 and the device region 155 belong to a continuous substrate 101. In some embodiments of the present disclosure, the P-type region is used to form a PMOS structure thereon, whereas the N-type region is used to form an NMOS structure thereon. Depending on circuit design, the regions 153, 155 may be used for forming different types of circuits. For example, the device region 153 may be used for forming, e.g., peripheral circuits, input/output (I/O) circuits, electrostatic discharge (ESD) circuits, and/or analog circuits and the device region 155 region may be used for forming logic circuits. Other regions for forming other types of circuits are contemplated and are intended to be included within the scope of the present disclosure.

In FIG. 13, an interfacial layer (IL) 150 is formed to surround the exposed surfaces of the first semiconductor layers 106. In some embodiments, the IL 150 may also form on the well portion 116 of the substrate 101. The IL 150 has a uniform thickness on the exposed surfaces of the first semiconductor layers 106 and on the well portion 116 of the substrate 101. The IL 150 may include or be made of an oxygen-containing material or a silicon-containing material, such as silicon oxide, silicon oxynitride, oxynitride, etc. In one embodiment, the IL 150 is silicon oxide. The IL 150 may be formed by first subjecting the first semiconductor layers 106 and the exposed well portion 116 of the substrate 101 to a wet process. The wet process may be any suitable wet cleaning process or self-compensation wet process. In some embodiments, the wet process is an etch process using at least ozone (O₃) and/or ammonium hydroxide (NH₄OH). For example, the wet process may include NH₄OH, HF or diluted HF, deionized (DI) water, tetramethylammonium hydroxide (TMAH), other suitable wet etching solution, or a combination thereof. In one embodiment, the wet process may be a standard clean-2 (SC2) followed by a standard clean-1 (SC1), where the SC2 is a mixture of DI water, hydrochloric (HCl) acid, and hydrogen peroxide (H₂O₂), and the SC1 is a mixture of DI water, NH₄OH, and H₂O₂. In some embodiments, an isopropyl alcohol (IPA) may be used after the SC1. Other suitable wet cleaning process, such as an APM process, which includes at least water (H₂O), ammonium hydroxide (NH₄OH), and hydrogen peroxide (H₂O₂), a HPM process, which includes at least H₂O, H₂O₂, and hydrogen chloride (HCl), a SPM process (also known as piranha clean), which includes at least H₂O₂ and sulfuric acid (H₂SO₄), or any combination thereof, may also be used.

Additionally or alternatively, the IL 150 may be formed by a wet oxidation process, which oxidizes an outer portion of the first semiconductor layers 106 and an outer portion of the exposed well portion 116 of the substrate 101. That is, the outer portion of the first semiconductor layers 106 and the exposed well portion 116 of the substrate 101 is or part of the IL 150. The outer portion surrounds and in contact with the first semiconductor layers 106 and the well portion 116 of the substrate 101 upon completion of the oxidation. In some embodiments, the IL 150 may be formed using an oxidation process such as thermal oxidation process, a rapid thermal oxidation (RTO) process, an in-situ stream generation (ISSG) process, or an enhanced in-situ stream generation (EISSG) process. In one example, the IL 150 is formed by subjecting the first semiconductor layers 106 and the well portion 116 of the substrate 101 to a rapid thermal anneal (RTA) in an oxygen-containing environment. The thermal oxidation may be performed at a temperature of about 600 degrees Celsius to about 1100 degrees Celsius, for a time span of about 10 seconds to about 30 seconds. The temperature and time span of the oxidation may contribute to the thickness of the IL 150. For example, higher temperatures and longer oxidation time spans may result in a thicker IL 150. Alternatively, the IL 150 may also be an oxide formed by CVD, ALD or any suitable conformal deposition technique.

In FIG. 14, a high-K (HK) dielectric layer 160 is formed over the exposed surfaces of the semiconductor device structure 100. In some embodiments, the HK dielectric layer 160 is in contact with the IL 150. The HK dielectric layer 160 is also formed on the exposed surface of the insulating material 118. The HK dielectric layer 160 may be a single layer or a multi-layer structure. In one embodiment, the HK dielectric layer 160 is a bi-layer structure including a first HK dielectric layer 160a and a second HK dielectric layer 160b. The first and second HK dielectric layers 160a, 160b may use a material chemically different from each other. Suitable materials for the HK dielectric layer 160 may include, but are not limited to, hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlOx), aluminum silicon oxide (AlSiO), zirconium oxide (ZrO), titanium oxide (TiO), tantalum oxide (Ta₂O₅), yttrium oxide (Y₂O₃), silicon oxynitride (SiON), or the like, or any material having a dielectric constant value greater than a dielectric constant of silicon oxide. The HK dielectric layer 160 may be a conformal layer formed by a conformal process, such as an ALD process or a CVD process. The HK dielectric layer 160 may have a thickness ranging from about 10 Angstroms to about 50 Angstroms.

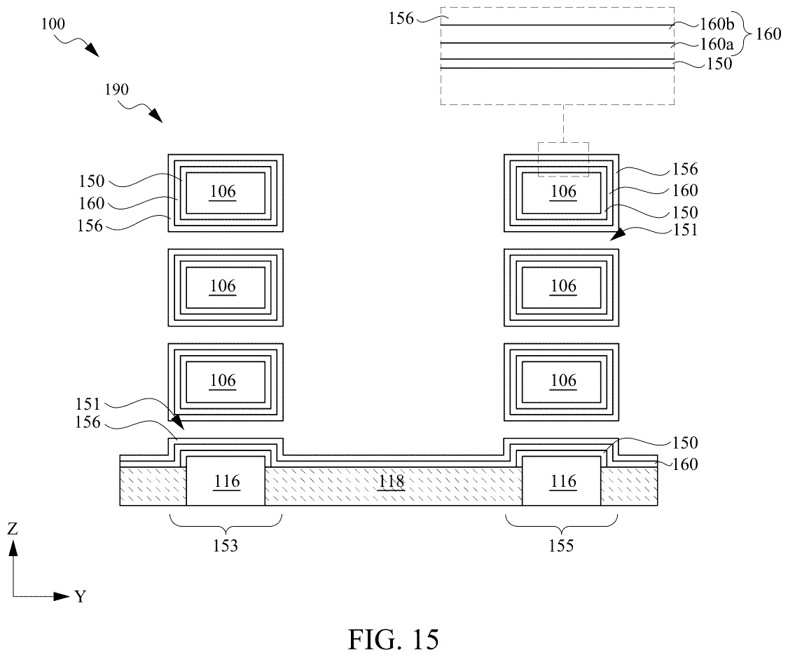

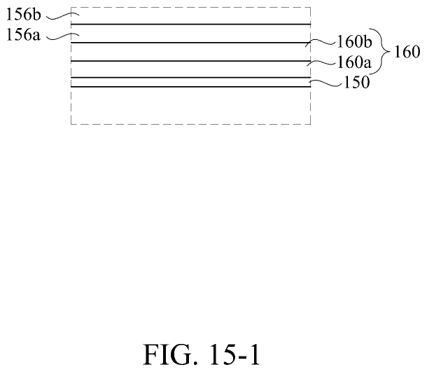

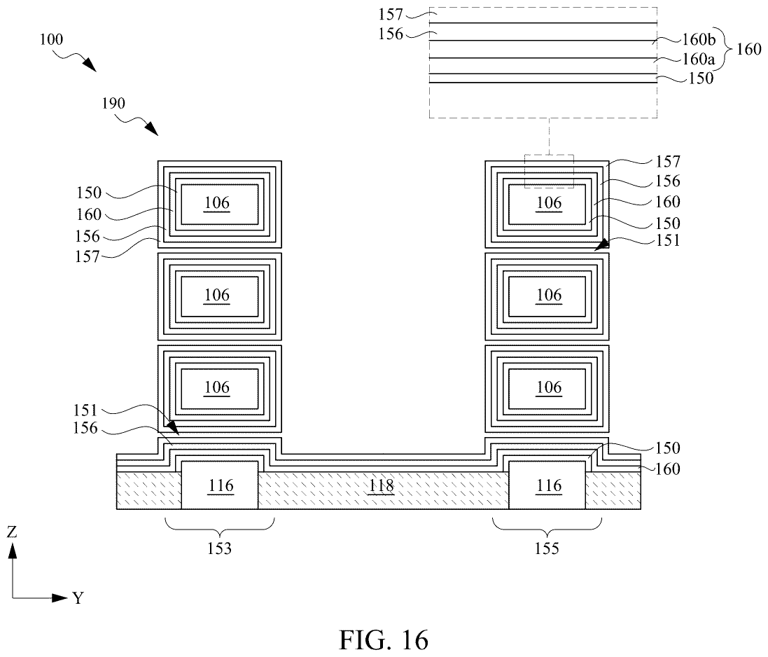

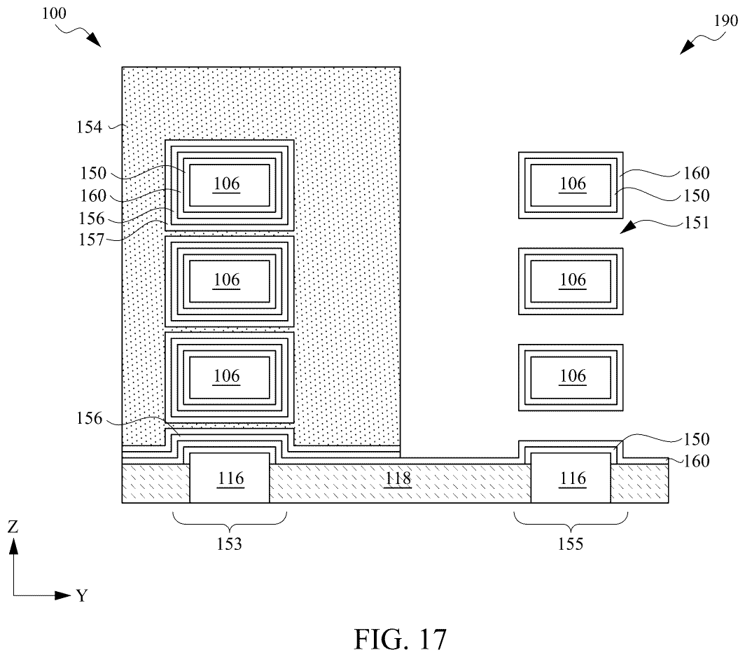

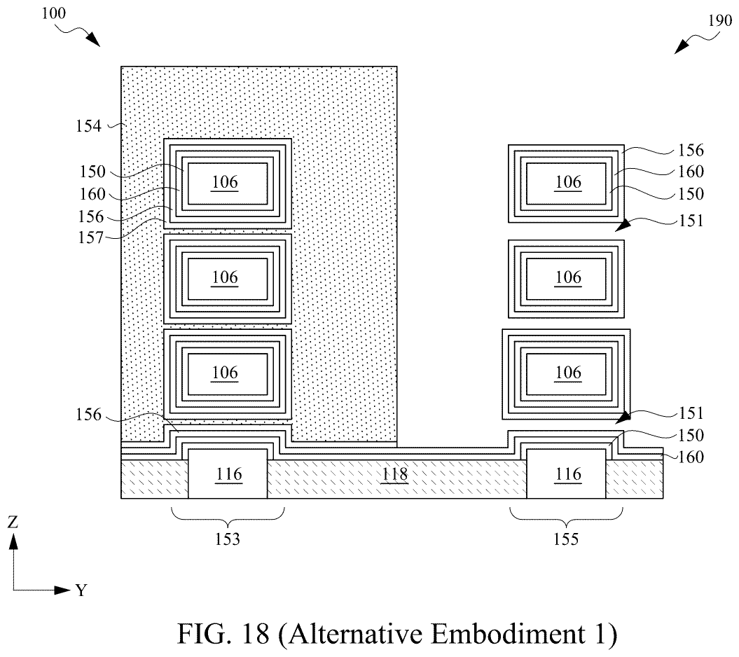

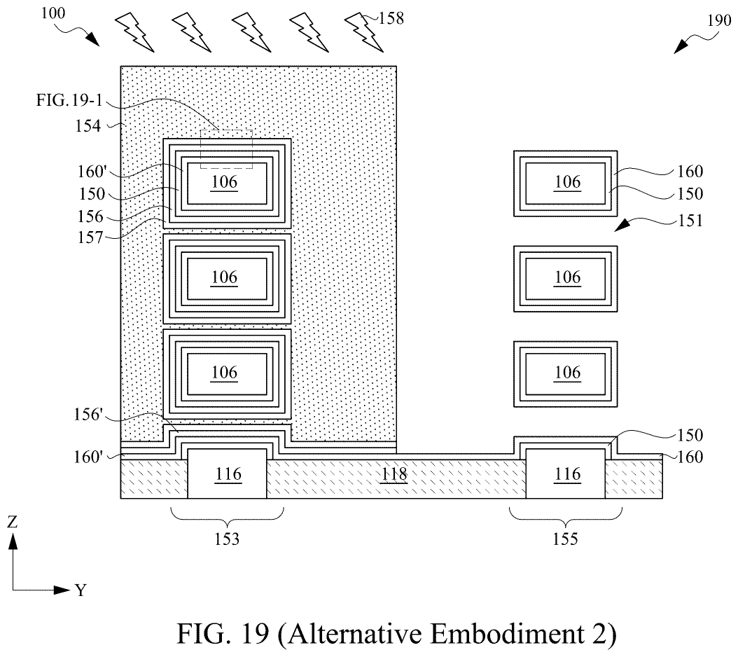

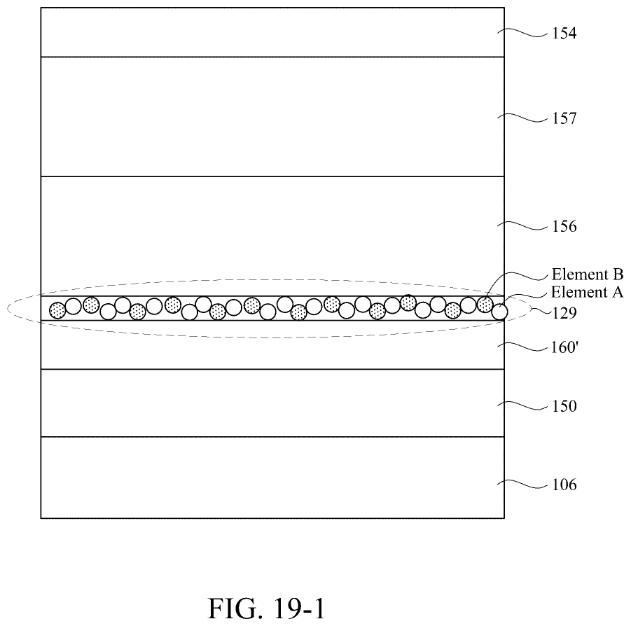

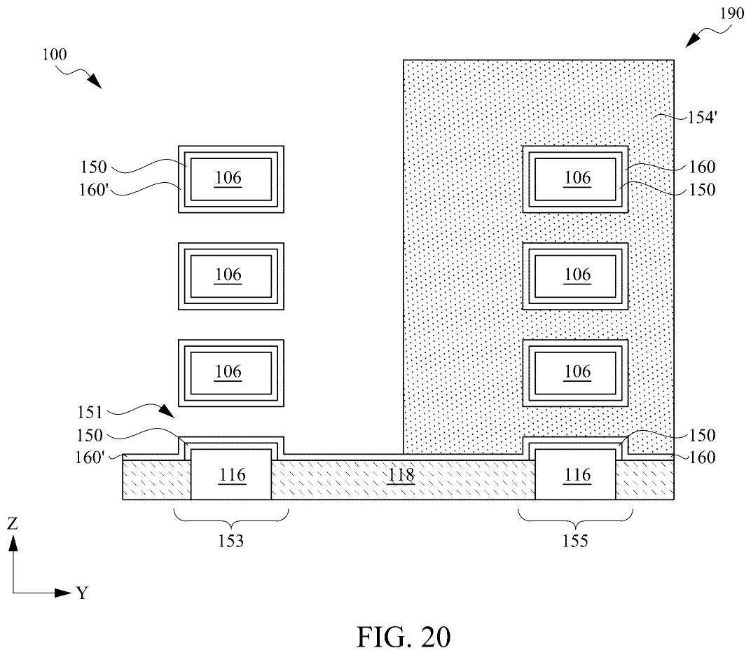

In FIG. 15, a tuning layer 156 is formed on the HK dielectric layer 160. The tuning layer 156 may serve as a dipole layer for Vth tuning. If the HK dielectric layer 160 is a multi-layer structure, the tuning layer 156 may be deposited on the first HK dielectric layer 160a. In some embodiments, the tuning layer 156 is a dielectric material containing element(s) suitable for Vₜₕ tuning for P-type devices. The tuning layer 156 may be nitride-based or an oxide-based dielectric material. In some embodiments, the tuning layer 156 is a metal nitride material, in which the metal may include, but is not limited to, aluminum (Al), titanium (Ti), hafnium (Hf), tantalum (Ta), zirconium (Zr), gallium (Ga), or the like, or combinations thereof. Exemplary metal nitride for the tuning layer 156 may include AlN, TiN, HfN, TaN, ZrN, GaN, or the like. The thickness of the tuning layer 156 serves as a key parameter for regulating the nitrogen incorporation in the HK dielectric 160, thereby controlling the V_{FB} shift and minimizing the CET penalty. As will be discussed in more detail below, the total thickness of the tuning layer 156 and the dipole layer 157 influences the concentration of metal and nitrogen within the tuning layer 156. This, in turn, affects the metal and nitrogen content in the HK dielectric layer 160, ultimately impacting the flat-band voltage (V_{FB}) and threshold voltages of the gate structures in the device.

In some embodiments, the tunning layer 156 is a metal oxide material, in which the metal may include, but is not limited to, Al, gallium (Ga), indium (In), zinc (Zn), germanium (Ge), Ti, or the like, or combinations thereof. Exemplary metal oxide for the tunning layer 156 may include AlOx, GaO, InO, ZnO, GeO, TiO, or the like.

In some embodiments, the tuning layer 156 is a metal oxynitride, in which the metal may be Al, Hf, Ti, Zr, lanthanum (La), or the like, or combinations thereof. Exemplary metal oxynitride for the tuning layer 156 may include AlON, HfON, TiON, ZrON, LaON, or the like.

In some embodiments, the tuning layer 156 may be a multi-layer structure including two or more materials discussed here. For example, the tuning layer 156 may be a bi-layer structure comprising AlN and AlON. FIG. 15-1 illustrates an embodiment where the tuning layer 156 includes a first layer 156a comprising AlN, for example, and a second layer 156b comprising AlON, for example.

In any case, the tuning layer 156 may be formed using a conformal deposition process, such as an ALD process. Other suitable deposition technique, such as CVD, MOCVD, or PECVD, etc., may also be used.

In cases where the tuning layer 156 includes AlN, the chemical precursors used for forming AlN may include an aluminum-containing precursor and a nitrogen-containing precursor. Exemplary aluminum-containing precursor may include, but is not limited to Aluminum alkyls (e.g., Trimethylaluminum (TMA, Al(CH₃)₃)), Aluminum hydroxide (Al(OH)₃) or aluminum oxide (Al₂O₃), Aluminum chloride (AlCl₃), etc. Exemplary nitrogen-containing precursor may include, but is not limited to ammonia (NH₃), nitrogen (N₂), hydrazine (N₂H₄), Trimethylamine (N(CH₃)₃).

In cases where the tuning layer 156 includes AlON, the chemical precursors used for forming AlON may include an aluminum-containing precursor, an oxygen-containing precursor, and a nitrogen-containing precursor. Exemplary oxygen-containing precursor may include, but is not limited to water (H₂O), oxygen (O₂), nitrous oxide (N₂O), etc. Oxygen-containing organic compounds, such as methanol (CH₃OH), ethanol (C₂H₅OH), and propanol (C₃H₇OH), or the like, may also be used. Exemplary aluminum-containing precursor and nitrogen-containing precursor may be those used for forming AIN as discussed above.

Alternatively, the tuning layer 156 may be a dielectric material containing element(s) suitable for Vth tuning for N-type devices. In such a case, the tuning layer 156 may be an oxide-based dielectric material. In some embodiments, the tuning layer 156 is a metal oxide material, in which the metal may include, but is not limited to, lanthanum (La), lutetium (Lu), scandium (Sc), yttrium (Y), thulium (Tm), gadolinium (Gd), magnesium (Mg), or combinations thereof. Exemplary metal oxide for the tuning layer 156 may include La₂O₃, LuOₓ, ScOₓ, Y₂O₃, Tm₂O₃, Gd₂O₃, MgO, or the like.

As will be discussed below, the tuning layer 156 work with the dipole layer 157 (FIG. 16) and the thickness of the tuning layer 156 may increase or compensate for the flat-band voltage (V_{FB}) and the threshold voltage Vth needed for P-type or N-type transistor devices. In various embodiments, the tuning layer 156 may have a thickness in a range between about 1 Angstroms and about 15 Angstroms, for example about 5 Angstroms to about 10 Angstroms. If the thickness of the tuning layer 156 is less than 1 Angstroms, the tuning layer 156 may not function as intended for effective V_{FB} and Vₜₕ tuning. On the other hand, if the thickness of the tuning layer 156 is greater than about 15 Angstroms, the gate fill window for the subsequent layers (e.g., dipole layer 157) may be negatively affected and the manufacturing cost is increased without significant advantage.

In FIG. 16, a dipole layer 157 is formed on the exposed surfaces of the tuning layer 156. Depending on the conductivity type of the nanosheet transistor, the dipole layer 157 may be configured to include positive polarity or negative polarity. The material of the dipole layer 157 and the tuning layer 156 are selected and function together as a bilayer P-dipole. The dipole layer 157 may also function as a patterned mask and be used to prevent oxidation of the tuning layer 156 (e.g., AlN or AlON). In cases where the nanosheet transistor at the device region 153 is designated as a P-type FET and the nanosheet transistor at the device region 155 is designated as an N-type FET, the dipole layer 157 can be a positive polarity dipole (p-dipole) layer formed from a material inherently including a positive polarity. For example, the dipole layer 157 may be an oxide-based dielectric material, such as a metal oxide material. In such a case, the metal may include, but is not limited to, Al, Ga, In, Zn, Ge, Ti, vanadium (V), or the like, or combinations thereof. Exemplary metal oxide for the dipole layer 157 may include AlOₓ, GaOₓ, InOₓ, ZnOₓ, GeOₓ, TiOₓ, VOₓ, or the like.

In cases where the dipole layer 157 includes AlOₓ, the chemical precursors used for forming AlOₓ may include an aluminum-containing precursor and an oxygen-containing precursor. Exemplary aluminum-containing precursor and oxygen-containing precursor may be those used for forming AlON as discussed above. The dipole layer 157 may be formed using a conformal deposition process, such as an ALD process. Other suitable deposition technique, such as CVD, MOCVD, or PECVD, etc., may also be used. In some embodiments, the dipole layer 157 and the tuning layer 156 may be deposited in the same process chamber without breaking the vacuum.

The total thickness of the tuning layer 156 and the dipole layer 157 is set to a fixed value since the dipole layer 157 is also used as a mask. In various embodiments, the dipole layer 157 and the tuning layer 156 may have a total thickness of about 30 Angstroms, and the thickness of the dipole layer 157 will vary depending on the thickness of the tuning layer 156. For example, if the tuning layer 156 has a thickness of about 10 Angstroms, then the dipole layer 157 may have a thickness of about 20 Angstroms. Therefore, the thicker the dipole layer 157, the thinner the tuning layer 156, or vice versa. It has been observed that when the thickness of the tuning layer 156 increases, a greater amount of nitrogen (in cases where the tuning layer 156 includes AlN or AlON) is driven into the HK dielectric layer 160 after the thermal treatment. This enhanced nitrogen incorporation in the HK dielectric layer 160 strengthens the blocking effect on metal elements (e.g., Al) in the tuning layer 156 due to stronger bonding characteristics and interactions between nitrogen and metal elements in the HK dielectric layer 160. As a result, the majority of metal (e.g., Al) is blocked from entering, or getting deeper in the HK dielectric layer 160, leading to lower concentration of metal (e.g., Al) in the HK dielectric layer 160. Conversely, when the thickness of the dipole layer 157 increases, the tuning layer 156 will decrease in thickness. Therefore, a lesser amount of nitrogen is driven into the HK dielectric layer 160 after the thermal treatment, resulting in a higher concentration of metal (e.g., Al) in the HK dielectric layer 160. By adjusting the thickness ratio between the tuning layer 156 and the dipole layer 157, the concentration of Al and N in the HK dielectric layer 160 can be modified, allowing for increase of the flat-band voltage (V_{FB}) of the gate structures to the desired value with minimal increase in CET.

In FIG. 17, a patterned mask layer 154 is formed to cover at least the nanosheet transistor at the device region 153, which is designated as a P-type FET in some embodiments. The mask layer 154 may first fill the openings 151 (FIG. 16) to a level so that the nanosheet transistors at the regions 153, 155 are submerged in the mask layer 154. The mask layer 154 may be any suitable masking material, such as a photoresist layer, a BARC (bottom anti-reflective coating) layer, a SOG (spin-on-glass) layer, or a SOC (spin-on-carbon) layer, and may be deposited by spin coating or any suitable deposition technique. Next, the mask layer 154 is patterned and etched to expose the nanosheet transistor at the device region 155, which is designated as an N-type FET in some embodiments. The tuning layer 156 and the dipole layer 157 at the device region 153 not covered by the mask layer 154 are removed using ash process and/or one or more etch processes, such as dry etch, wet etch, or a combination thereof.

In some embodiments, the etch processes is performed to expose the HK dielectric layer 160 at the device region 155, as shown in FIG. 17.

In some embodiments, the etch processes is performed until the tuning layer 156 at the device region 155 is exposed, as shown in FIG. 18.

In some embodiments, the etch processes is performed to expose the HK dielectric layer 160 at the device region 155, and the semiconductor device structure 100 is subjected to a thermal treatment 158, as shown in FIG. 19. The thermal treatment drives the elements (e.g., Al) from the tuning layer 156 into the underlying HK dielectric layer 160 at the device region 153. The HK dielectric layer 160 at the device region 155 does not contain elements from the tuning layer 156. In some embodiments, the thermal treatment may also drive elements (e.g., Al) of the dipole layer 157 into the HK dielectric layer 160. In cases where the tuning layer 156 includes AlN or AlON, elements (e.g., Al) in the tuning layer 156 are driven into and mixed with the HK dielectric layer 160 to form an intermixed layer 129 as a result of the thermal treatment. The intermixed layer 129 alone, or the entire HK dielectric layer 160, can be considered as a modified HK dielectric layer 160′. The term “intermixed layer” as used in this disclosure denotes a reaction product of the HK dielectric layer 160 and the tuning layer 156, which can be a compound, a composition or a mixture, depending on the thermal treatment used. In some embodiments, the intermixed layer 129 can be the HK dielectric layer 160 doped with elements (e.g., Al) from the tuning layer 156.

FIG. 19-1 is an enlarged view of a portion of the semiconductor device structure 100 showing the intermixed layer 129 in the modified HK dielectric layer 160′ at and/or near an interface defined by the modified HK dielectric layer 160′ and the tuning layer 156. The intermixed layer 129 may have elements A (e.g., Al) and elements B (e.g., N) with a concentration profile gradually and continuously changed along the thickness of the intermixed layer 129. In one embodiment, the intermixed layer 129 has a first concentration of Al and N, respectively, at an interface of the intermixed layer 129 and the tuning layer 156, and a second concentration of Al and N, respectively, at an interface of the intermixed layer 129 and the modified HK dielectric layer 160′, wherein the first concentration is greater than the second concentration. In some embodiments, Al may have a higher concentration than N at the interface between the intermixed layer 129 and the tuning layer 156, potentially due to its larger atomic radius compared to N, which may influence its diffusion and distribution characteristics.

The thermal treatment may be performed in-situ or ex-situ and can be any type of anneal, such as rapid thermal anneal, a spike anneal, a soak anneal, a laser anneal, a furnace anneal, etc. The thermal treatment may be performed for about 0.05 seconds to about 60 minutes, such as about 10 seconds to about 30 seconds, and at a temperature range of about 450° C. to about 1200° C. The thermal treatment may be performed in an atmosphere of gas, such as an oxygen-containing gas, a hydrogen-containing gas, an argon-containing gas, a helium-containing gas, or any combinations thereof. Exemplary gas may include, but are not limited to, N₂, NH₃, O₂, N₂O, Ar, He, H, etc.

In FIG. 20, a mask layer 154′, such as the mask layer 154, is formed to cover at least the nanosheet transistor at the device region 155, which is designated as an N-type FET in some embodiments. The mask layer 154′ protects the HK dielectric layer 160 and the IL 150 at the device region 155 during the subsequent etching process. Next, the mask layer 154 at the device region 153 is patterned and etched to expose the nanosheet transistor, which is designated as a P-type FET in some embodiments. The dipole layer 157, the tuning layer 156 at the device region 153 not covered by the mask layer 154 are removed using ash process and/or one or more etch processes, such as dry etch, wet etch, or a combination thereof. The etch processes expose the surfaces of the HK dielectric layer 160 at the device region 153.

Depending on the applications, the threshold voltage of the N-type and/or P-type FETs at regions 153, 155 can be tuned by, for example, forming and varying the thickness of one or more dipole layers 157 and the tuning layer 156 to achieve different concentrations of elements as discussed above. In addition, the etch processes discussed above with respect to FIGS. 17-19 may be configured so that different arrangements of dipole layer 157 and tuning layer 156 are provided at regions 153, 155, respectively. Integrated circuit devices such as the semiconductor device structure 100 may include various transistors having different threshold voltages based on their function in the IC device. For example, input/output (IO) transistors may have the highest threshold voltages due to the high current handling required for the IO transistors. Core logic transistors may have the lowest threshold voltages to achieve higher switching speeds at lower operating power. A third threshold voltage between that of the IO transistors and that of the core logic transistors may be employed for other functional transistors, such as static random access memory (SRAM) transistors. By keeping and/or removing the dipole layer/tuning layer in different regions, the nanosheet FETs in different regions of the semiconductor device structure can be operated at different threshold voltages required for different applications.

In FIG. 21, the mask layer 154′ is removed and a gate electrode layer 165 is formed on modified HK dielectric layer 160′ at the device region 153 and the HK dielectric layer 160 at the device region 155. The gate electrode layer 165 wraps around each first semiconductor layer 106 and filles the opening 151 (FIGS. 19 and 20) at the device region 153, 155. The gate electrode layer 165 may be deposited so that at least the nanosheet transistors at the regions 153, 155 are submerged in the gate electrode layer 165. In some embodiments, the gate electrode layer 165 is deposited to a height over a top surface of the HK dielectric layer 160, 160′ over the topmost first semiconductor layer 106. In some embodiments, the gate electrode layer 165 may be formed using multiple layers, each layer deposited sequentially adjacent to each other using a highly conformal deposition process such as ALD. Other deposition technique such as PVD, CVD, or electro-plating may also be used. While not shown, the gate electrode layer 165 may include a capping layer, a barrier layer, an n-metal work function layer, a p-metal work function layer, and a fill material. The capping layer and the barrier layer may be metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be formed of a material different from the capping layer. The n-metal work function layer may be formed from a metallic material such as W, Cu, AlCu, TiAlC, TiAlN, Ti, TiN, Ta, TaN, Co, Ni, Ag, Al, TaAl, TaAlC, TaC, TaCN, TaSiN, Mn, Zr, other suitable n-type work function materials, or combinations thereof. The p-metal work function layer may be formed from a metallic material such as W, Al, Cu, TiN, Ti, TiAlN, Ta, TaN, Co, Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Once the n-metal work function layer and the p-metal work function layer are formed, the fill material is deposited to fill a remainder of the opening 151. The fill material may be a material such as W, Al, Cu, AlCu, W, Ti, TiAlN, TaC, TaCN, TaSiN, Mn, Zr, TiN, Ta, TaN, Co, Ni, combinations of these, or the like.

While various processes in FIGS. 17-20 describe an approach using a mask layer 154 to selectively remove tuning layer 156 and dipole layer 157 from the nanosheet transistor at the device region 155, in some embodiments the dipole layer 157 at the device region 155 is removed to expose the tuning layer 156, and then the dipole layer 157 at the device region 153 is used as a patterned mask to further remove the tuning layer 156 at the device region 155. Next, the dipole layer 157 and tuning layer 156 at the device region 153 are subjected to the thermal treatment to form the intermixed layer 129 in the modified HK dielectric layer 160′. The dipole layer 157 and tuning layer 156 at the device region 153 are then removed, followed by the formation of the gate electrode layer 165 to result in the structure shown in FIG. 21.

FIG. 22 shows an enlarged view of a portion of the semiconductor device structure 100 of FIG. 21 in accordance with some embodiments. As discussed above, the first semiconductor layer 106 at the device region 153 is surrounded by, in order, the IL 150, the modified HK dielectric layer 160′, the intermixed layer 129, the gate electrode layer 165. The first semiconductor layer 106 at the device region 155 is surrounded by, in order, the IL 150, the HK dielectric layer 160, the gate electrode layer 165. The modified HK dielectric layer 160′ and the intermixed layer 129 at the device region 153 may have a thickness T1, and the HK dielectric layer 160 at the device region 155 may have a thickness T2 that is substantially the same as the thickness T1.

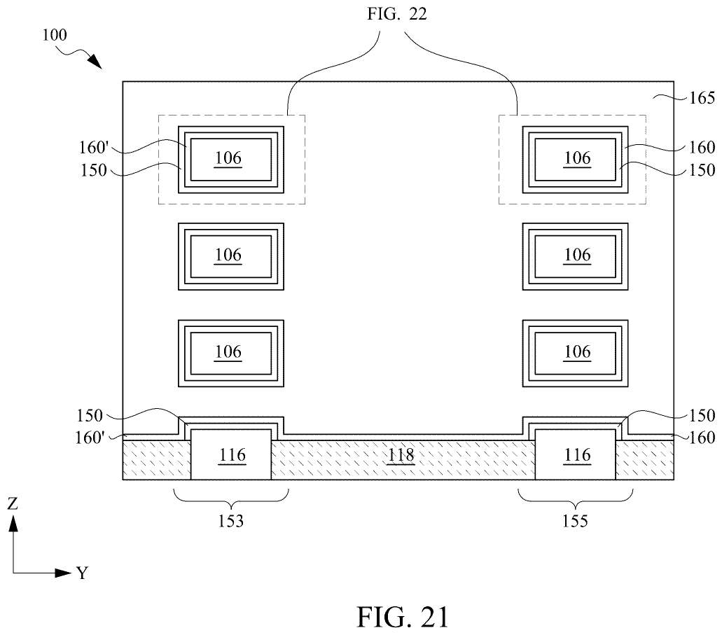

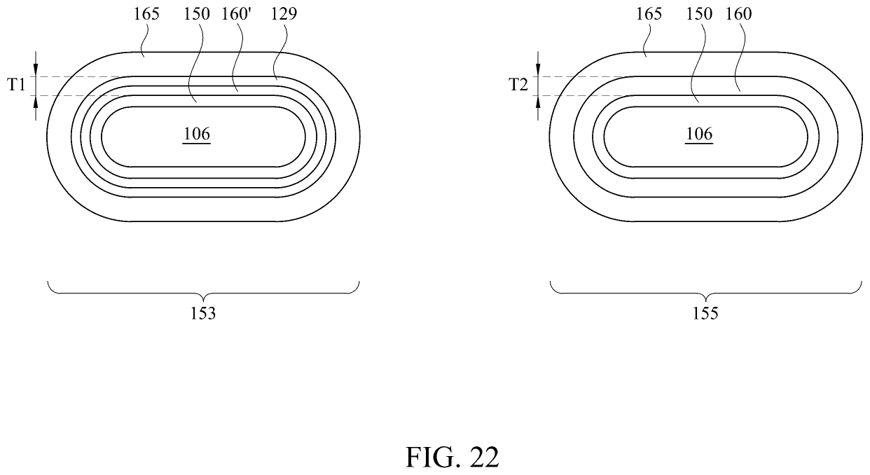

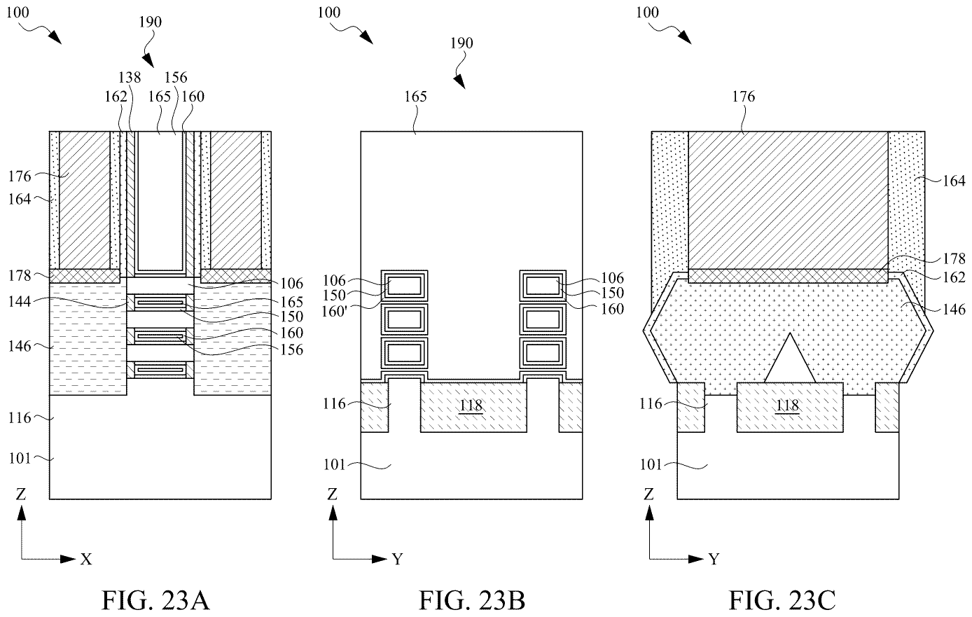

In FIGS. 23A-23C, contact openings are formed through the ILD layer 164 and the CESL 162 to expose the epitaxial S/D feature 146. A silicide layer 178 is then formed on the epitaxial S/D features 146 to conductively couple the epitaxial S/D features 146 to the subsequently formed S/D contacts 176. The silicide layer 178 may be formed by depositing a metal source layer over the epitaxial S/D features 146 and performing a rapid thermal annealing process. The metal source layer includes a metal layer selected from W, Co, Ni, Ti, Mo, and Ta, or a metal nitride layer selected from tungsten nitride, cobalt nitride, nickel nitride, titanium nitride, molybdenum nitride, and tantalum nitride. During the rapid anneal process, the portion of the metal source layer over the epitaxial S/D features 146 reacts with silicon in the epitaxial S/D features 146 to form the silicide layer 178. Unreacted portion of the metal source layer is then removed.

After formation of the silicide layer 178, a conductive material is formed in the contact openings and form the S/D contacts 176. The conductive material may be made of a material including one or more of Ru, Mo, Co, Ni, W, Ti, Ta, Cu, Al, TiN and TaN. While not shown, a barrier layer (e.g., TiN, TaN, or the like) may be formed on sidewalls of the contact openings prior to forming the S/D contacts 176. Then, a planarization process, such as CMP, is performed to remove excess deposition of the contact material and expose the top surface of the gate electrode layer 165.

It is understood that the semiconductor device structure 100 may undergo further complementary metal oxide semiconductor (CMOS) and/or back-end-of-line (BEOL) processes. For example, gate contacts may be formed to electrically couple to the gate electrode layer 165. An interconnect structure may be formed over the S/D contacts 176 and gate contacts. The interconnect structure may include a plurality of dielectric layers and metallic features, including conductive traces and conductive vias, embedded in the dielectric layers, which form electrical connection between various devices on the substrate 101. The semiconductor device structure 100 may also include backside contacts (not shown) on the backside of the substrate 101 by flipping over the semiconductor device structure 100, removing the substrate 101, and selectively connecting source or drain feature/terminal of the epitaxial S/D features 146 to a backside power rail (e.g., positive voltage VDD or negative voltage VSS) through the backside contacts. Depending on the application, the source or drain feature/terminal of the epitaxial S/D features 146 and the gate electrode layer 172 may be connected to a frontside power source.

Various embodiments of the present disclosure provide an improved approach of using tuning layers (formed of metal nitrides) and dipole layers (cluster mask layer) as bilayer p-dipole layers for controlling the V_{FB} of the gate structure. The thickness of the tuning layer (e.g., tuning layer 156) serves as a key parameter for regulating the nitrogen incorporation in the HK dielectric (e.g., HK dielectric layer 160), thereby controlling the V_{FB} shift while minimizing the CET penalty. The total thickness of the tuning layer and the dipole layer (e.g., dipole layer 157) influences the concentration of metal and nitrogen within the tuning layer. This, in turn, affects the metal and nitrogen content in the HK dielectric layer 160, ultimately impacting the flat-band voltage (V_{FB}) and threshold voltages of the gate structures in the device.

An embodiment is a method for forming a semiconductor device structure. The method includes forming an interfacial layer (IL) to surround each of a plurality of semiconductor channel layers at first and second device regions, forming a high-K (HK) dielectric layer over the IL, forming a tuning layer over the HK dielectric layer, the tuning layer comprising elements suitable for devices having a first conductivity type, forming a dipole layer over the tuning layer at the first and second device regions, wherein the tuning layer and the dipole layer are sequentially formed in a processing chamber without breaking the vacuum, and the dipole layer comprises elements suitable for devices having the first conductivity type, removing the dipole layer over the selected semiconductor channel layers at the second device region, subjecting the tuning layer to a thermal treatment so that elements from the tuning layer is driven into the HK dielectric layer at the first device region, removing the dipole layer and the tuning layer over the selected semiconductor channel layers at the first device region, and forming a gate electrode layer to surround each semiconductor channel layer at the first and second device regions.

Another embodiment is a method for forming a semiconductor device structure. The method includes forming a first dipole layer over a high-K (HK) dielectric layer on a first channel layer and a second channel layer, respectively, forming a second dipole layer over the first dipole layer, the second dipole layer being chemically different than the first dipole layer, removing the second dipole layer over the second channel layer, subjecting the first and second dipole layers over the first channel layer to a thermal treatment to form an intermixed layer in the HK dielectric layer on the first channel layer, removing the first and second dipole layers over the first channel layer, and forming a gate electrode layer over the first and second channel layers.

A further embodiment is a semiconductor device structure. The structure includes a first semiconductor channel layer at a first device region, a second semiconductor channel layer at a second device region, a first gate dielectric layer disposed over the first semiconductor channel layer, the first gate dielectric layer is doped with a first element containing metal and a second element containing nitrogen, a second gate dielectric layer disposed over the second semiconductor channel layer, wherein the second gate dielectric layer has a first thickness, a gate electrode layer disposed over the first gate dielectric layer and the second gate dielectric layer, respectively, and an intermixed layer disposed between and in contact with the gate electrode layer and the first gate dielectric layer, wherein the intermixed layer comprises the first and second elements, and the intermixed layer and the first gate dielectric layer has a second thickness that is substantially the same as the first thickness.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for forming a semiconductor device structure, comprising:
forming an interfacial layer (IL) to surround each of a plurality of semiconductor channel layers at first and second device regions;
forming a high-K (HK) dielectric layer over the IL;
forming a tuning layer over the HK dielectric layer, the tuning layer comprising elements suitable for devices having a first conductivity type;
forming a dipole layer over the tuning layer at the first and second device regions, wherein the tuning layer and the dipole layer are sequentially formed in a processing chamber without breaking the vacuum, and the dipole layer comprises elements suitable for devices having the first conductivity type;
removing the dipole layer over the selected semiconductor channel layers at the second device region;
subjecting the tuning layer to a thermal treatment so that elements from the tuning layer is driven into the HK dielectric layer at the first device region;
removing the dipole layer and the tuning layer over the selected semiconductor channel layers at the first device region; and
forming a gate electrode layer to surround each semiconductor channel layer at the first and second device regions.

2. The method of claim 1, further comprising:
after removing the tuning layer over the selected semiconductor channel layers at the second device region, removing the tuning layer over the selected semiconductor channel layers at the second device region.

3. The method of claim 1, wherein the tuning layer comprises a nitride-based or an oxide-based dielectric material.

4. The method of claim 3, wherein the tuning layer is a metal nitride and/or metal oxynitride.

5. The method of claim 4, wherein the metal is aluminum (Al), titanium (Ti), hafnium (Hf), tantalum (Ta), zirconium (Zr), or gallium (Ga), or the like.

6. The method of claim 4, wherein the tuning layer is aluminum nitride (AlN).

7. The method of claim 4, wherein the tuning layer is aluminum oxynitride (AlON).

8. The method of claim 4, wherein the tuning layer has a thickness of about 1 Angstrom to about 15 Angstroms.

9. The method of claim 8, wherein the tuning layer and the dipole layer have a total thickness of about 30 Angstroms.

10. A method for forming a semiconductor device structure, comprising:
forming a first dipole layer over a high-K (HK) dielectric layer on a first channel layer and a second channel layer, respectively;
forming a second dipole layer over the first dipole layer without vacuum break, the second dipole layer being chemically different than the first dipole layer;
removing the second dipole layer over the second channel layer;
subjecting the first and second dipole layers over the first channel layer to a thermal treatment to form an intermixed layer in the HK dielectric layer on the first channel layer;
removing the first and second dipole layers over the first channel layer; and
forming a gate electrode layer over the first and second channel layers.

11. The method of claim 10, further comprising:
after removing the second dipole layer over the second channel layer, removing the first dipole layer over the second channel layer.

12. The method of claim 11, wherein the first and second dipole layers are removed using the second dipole layer over the first channel layer as a mask.

13. The method of claim 10, wherein the first dipole layer and the second dipole layer have a total thickness of about 30 Angstroms.

14. The method of claim 10, wherein the intermixed layer is a reaction product of the HK dielectric layer and the first dipole layer.

15. The method of claim 14, wherein the first dipole layer is a metal nitride and/or metal oxynitride.

16. A semiconductor device structure, comprising:
a first semiconductor channel layer at a first device region;
a second semiconductor channel layer at a second device region;
a first gate dielectric layer disposed over the first semiconductor channel layer, the first gate dielectric layer is doped with a first element containing metal and a second element containing nitrogen;
a second gate dielectric layer disposed over the second semiconductor channel layer, wherein the second gate dielectric layer has a first thickness;
a gate electrode layer disposed over the first gate dielectric layer and the second gate dielectric layer, respectively; and
an intermixed layer disposed between and in contact with the gate electrode layer and the first gate dielectric layer, wherein the intermixed layer comprises the first and second elements, and the intermixed layer and the first gate dielectric layer has a second thickness that is substantially the same as the first thickness.

17. The semiconductor device structure of claim 16, wherein the first and second elements in the intermixed layer has a first concentration and the first and second elements in the first gate dielectric layer has a second concentration that is lower than the first concentration.

18. The semiconductor device structure of claim 16, wherein the intermixed layer is a reaction product of the first gate dielectric layer and a metal nitride or metal oxynitride.

19. The semiconductor device structure of claim 16, wherein the intermixed layer is a reaction product of the first gate dielectric layer and a metal nitride and metal oxynitride.

20. The semiconductor device structure of claim 16, wherein the intermixed layer is a reaction product of the first gate dielectric layer and a metal oxide.
